(19) United States
(12) Patent Application Publication
(10) Pub. No.: US 2007/0081414 A1
(43) Pub. Date: Apr. 12, 2007

(54) System and method of on-circuit asynchronous communication, between synchronous subcircuits

(76) Inventors: Cesar Douady, Orsay (FR); Philippe Boucard, Le Chesnay (FR); Luc Montperrus, Montigny Le Bretonneux (FR)

Correspondence Address: MEYERTONS, HOOD, KIVLIN, KOWERT & GOETZEL, P.C., 700 LAVACA, SUITE 800, AUSTIN, TX, 78701, US

(21) Appl. No.: 11/399,293

(22) Filed: Apr. 6, 2006

(30) Foreign Application Priority Data
Sep. 12, 2005 (FR) 0509279

(51) Int. Cl. G11C 8/00

(52) U.S. Cl. 365/233

(57) ABSTRACT

The system for on-circuit asynchronous communication, between synchronous subcircuits, includes a first synchronous subcircuit regulated by a first clock frequency, which sends requests to a second synchronous subcircut regulated by a second clock frequency. The first subcircuit transmits data to the second subcircuit through a first mesochronous unidirectional communication link, and the second subcircuit transmits availability tokens which report the availability of an additional elementary memory location in the queue situated at the extremity of the first mesochronous unidirectional communication link to the first subcircuit, via a second mesochronous unidirectional communication link. The first subcircuit comprises means of transmission for directly transmitting to the second subcircuit data of a size that is at most equal to the size corresponding to the elementary memory locations available in the queue.

### BACKGROUND OF THE INVENTION

1. Field of the Invention

The invention pertains to a system and a method of on-circuit asynchronous communication, between synchronous subcircuits.

2. Description of the Relevant Art

Submicron technologies make it possible to integrate a growing number of functionalities onto one and the same silicon chip, and to thus obtain veritable complete systems, or “Systems on Chip.” In such systems, it is necessary to manage the problems of communication between the various subcircuits.

Solutions using a communication bus or a communication network exist.

When using a communication bus, links, generally bidirectional, are shared by several agents or communication elements which use common resources in turn.

When using a communication network, the connections are generally point-to-point unidirectional communications, linking the agents directly together, or by way of switching elements. Arbitration is performed in the switching elements by means of routing tables. Interoperability is ensured by diverse specific interfaces.

The production of such on-silicon systems poses several problems, in particular due to the operational limitations of computer-aided design tools, as well as to the rapid progress in the speed of logic gates relative to the progress in the speed of transmission of signals in wires. Consequently, the transmission of information over significant distances is a critical problem.

Furthermore, it is difficult, on such systems, to maintain the clocks coherence, and the dispersion of the clocks is inevitable. It becomes extremely difficult, or even impossible, to maintain a complete system entirely synchronous. It is then possible to use systems of globally asynchronous and locally synchronous type, or GALS, for which the system is divided into several synchronous subsystems of reasonable sizes communicating together asynchronously.

The systems of globally asynchronous and locally synchronous type generally use, for their asynchronous global communications protocol, acknowledgements of receipt, also known as “hand shaking” protocols.

When a sender subcircuit and a receiver subcircuit are respectively ready to send and receive data, the sender dispatches a token, then the receiver receives the token and dispatches an acknowledgement of receipt, or OK, to signify that he has indeed received the token. The sender then dispatches an initiation signal to the receiver, signifying that the sender is ready to dispatch the token, and the receiver returns a token to the sender, signifying that it is ready to receive.

Such systems generate latency in the transmission of the data between synchronous subsystems, and utilize the available bandwidth poorly.

### SUMMARY OF THE INVENTION

An aim of the invention is to optimize the use of the available bandwidth between two synchronous subsystems.

Another aim of the invention is to facilitate and reduce the cost of production and testing of such circuits.

Thus, according to an embodiment, there is proposed a system for on-circuit asynchronous communication, between synchronous subcircuits. The system includes a first synchronous subcircuit regulated by a first clock frequency, suitable for sending requests to a second synchronous subcircuit regulated by a second clock frequency. The first subcircuit transmits data to the second subcircuit through a first mesochronous unidirectional communication link, and the second subcircuit transmits tokens to the first subcircuit through a second mesochronous unidirectional communication link. The first mesochronous unidirectional communication link includes a memory organized as a queue situated at the end of communication of the first link. An elementary memory location-of the queue has a predetermined size. The second synchronous subcircuit includes sending means for transmitting to the first subcircuit an availability token for an additional elementary memory location in the queue as soon as an elementary memory location of the queue is read by the second subsystem. The first subcircuit includes means of transmission for transmitting directly to the second subcircuit data of a size at most equal to the size corresponding to the elementary memory locations available in the queue.

A request is a unidirectional transfer of information.

Such a system makes it possible to optimize the use of the bandwidth between two synchronous subcircuits, as well as to decrease the latency of the system.

Furthermore, the cost of producing and validating such a system is decreased.

In an embodiment, the first subcircuit includes means of determination of the number of elementary memory locations available, on the basis of the availability tokens.

The first subcircuit therefore knows at any instant the amount of data that it can transmit to the second subcircuit as a function of the memory size available in the queue.

Stated otherwise, the first subcircuit can successively transmit several data packets to the second subcircuit, without having to wait, between two sendings of data packets, for a token from the second subcircuit indicating that it can receive the next packet of data to be transmitted. The use of the bandwidth is therefore optimized.

In an embodiment, the queue is write-regulated by the first clock frequency, and read-regulated by the second clock frequency.

In an embodiment, the queue includes a number of elementary memory locations at least equal to the number of cycles of the clock having the lowest regulating frequency, allowing a transfer of data from the first subsystem to the second subsystem, and the transmission from the second subsystem to the first subsystem of an availability token for an additional elementary memory location in the queue.

The size of the queue is then optimized, so as to avoid problems of increased latency.

For example, a mesochronous unidirectional communication link includes means of intermediate synchronization of the data transmitted by the link.

Specifically, it may be necessary to resynchronize the data transmitted on the mesochronous unidirectional communication link, when the length of the link so necessitates.

Furthermore, a plurality of mesochronous unidirectional communication links of like direction, have a clock regulating frequency transmitted in common.

The number of clock regulating signals to be transmitted is then sharply reduced, since a single one common to a plurality of links can be transmitted.

Furthermore, the system includes means of testing of the system by a device for generating test vectors. The means of testing includes means for rendering the queues synchronous.

The globally asynchronous and locally synchronous system can then be tested, by means of existing tools, such as test vector generators or “ATPGs.”

Advantageously, the system furthermore includes means of stopping/starting the first and second subcircuits. The stopping/starting means includes means of dispatching a signal representative of the activity of one of the subcircuits jointly with the respective signal representative of the clock regulating frequency of the subcircuit. The stopping/starting means also includes means for resetting to zero the determined number of elementary memory locations available in the queue of the second subcircuit when the first subcircuit or the second subcircuit becomes inactive, and means for sending the number of availability tokens corresponding to the number of elementary memory locations available in the queue, when the first and second subcircuits are both active again.

It is thus possible to manage a partial or total reinitiation of the system, and decrease the consumption thereof.

According to another embodiment, a method of on-circuit asynchronous communication, between synchronous subcircuits, is also proposed. The circuit including a first synchronous subcircuit regulated by a first clock frequency, suitable for sending requests to a second synchronous subcircuit regulated by a second clock frequency. The first subcircuit transmits data to the second subcircuit through a first mesochronous unidirectional communication link, and the second subcircuit transmits tokens to the first subcircuit through a second mesochronous unidirectional communication link. The first mesochronous unidirectional communication link includes a memory organized as a queue situated at the end of communication of the link. An elementary memory location of the queue has a predetermined size. An availability token for an additional elementary memory location in the queue is transmitted to the first subcircuit as soon as an elementary memory location of the queue is read by the second subcircuit. Data of a size at most equal to the size corresponding to the elementary memory locations available in the queue are transmitted directly from the first subcircuit to the second subcircuit.

It is possible to perform a partition of a large subsystem into small subsystems of reasonable dimensions for the computer-aided design tools, while avoiding the need to manage or budget system time constraints. The management or budgeting of the time constraints is replaced by the measurement of the phase shift or dispersion between various signals of the mesochronous links (or “skew”), this being easier to perform.

Budgeting of the time constraints signifies apportioning a cycle time constraint between the path that starts from a sender flip-flop of a first subcircuit, the path that links the first subcircuit to the second subcircuit, and the path that arrives at a receiver flip-flop of the second subcircuit. This apportionment is generally estimated at the start of design, and is refined when the circuit synthesis results are refined, which often entails significant problems at the end of design.

The method therefore makes it possible to go from a constraint on a cycle time to a simplified constraint of dispersion of edges that is easier to effect and more easily adjustable through a slight increase in the latency, without modifying the clock regulating frequency.

Advantageously, the circuit is tested with a device for generating test vectors, rendering the queues synchronous.

Furthermore, the stopping/starting of the first and second subcircuits can be managed by dispatching a signal representative of the activity of one of the subcircuits jointly with the respective signal representative of the clock regulating frequency of the subcircuit, by resetting to zero the determined number of elementary memory locations available in the queue of the second subcircuit when the first subcircuit or the second subcircuit becomes inactive, and by sending the number availability tokens corresponding to the number of elementary memory locations available in the queue, when the first and second subcircuits are both active again.

According to an embodiment, a use of a method as described previously, to perform a hierarchical partition of large circuits into small subcircuits with a simplified logical synthesis of the circuit, is also proposed.

### BRIEF DESCRIPTION OF THE DRAWINGS

Other aims, characteristics and advantages of the invention will become apparent on reading the following description, given by way of nonlimiting examples, and offered with reference to the appended drawings, in which:

FIG. 1 illustrates an embodiment of a system;

FIG. 2 is a diagram of a data transmission on a rising edge of the clock signal with sampling of the data at reception on the falling edge of the clock signal;

FIG. 3 is a diagram of an embodiment of the queue with two clock domains;

FIG. 4 is a diagram of a mesochronous unidirectional communication link including intermediate synchronizations;

FIG. 5 is a diagram of an embodiment of a system with common pooling of clock regulating frequencies;

FIGS. 6 and 7 illustrate the partitioning of a system into several synchronous subcircuits; and

FIG. 8 is a diagrammatic view of means of testing of the system.

While the invention is susceptible to various modifications and alternative forms, specific embodiments thereof are shown by way of example in the drawings and will herein be described in detail. It should be understood, however, that the drawing and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Represented in FIG. 1 are two synchronous subcircuits SC1, SC2 of an asynchronous communication system. The first subcircuit SC1 includes a register REG1 and a memory organized as a queue FIFO2. The second subcircuit SC2 includes a memory organized as a queue FIFO1 and a flip-flop BASC1.

A first mesochronous unidirectional communication link LCUM1 links the register REG1 and the queue FIFO1. A second mesochronous unidirectional communication link LCUM2 links the flip-flop BASC1 to the queue FIFO2.

The first synchronous subcircuit SC1 is regulated by a first clock frequency H₁, and sends requests to the second synchronous subcircuit SC2 regulated by a second clock frequency H₂.

The queue FIFO2 and the register REG1 share the same signal of first clock regulating frequency, and the queue FIFO1 and the flip-flop BASC1 share the same signal of second clock regulating frequency.

The first subcircuit SC1 transmits data to the second subcircuit SC2 through the first mesochronous unidirectional communication link LCUM1. The data transmitted represent, for example, information or control data.

The second subcircuit SC2 transmits information to the first subcircuit SC1 through the second mesochronous unidirectional communication link LCUM2.

The first mesochronous unidirectional communication link LCUM1 is furnished with the memory organized as a queue FIFO1 at its end of the second subcircuit SC2. The queue FIFO1 includes a plurality of elementary memory locations of predetermined size.

The data sent on the first mesochronous unidirectional communication link LCUM1 are done so from the register REG1.

Furthermore, the first clock frequency H₁ is also transmitted by the first mesochronous unidirectional communication link LCUM1.

The queue FIFO1 is write-regulated by the first clock frequency H₁, and read-regulated by the second clock frequency H₂.

As soon as an elementary memory location of the queue FIFO1 is read by the subcircuit SC2, the flip-flop BASC1 of the second subcircuit SC2 transmits an availability token IDE for an additional elementary memory location in the queue FIFO1, to the first subcircuit SC1.

The expression reading an elementary memory location in a queue is understood to mean accessing the content of this location, and rendering this location available for writing.

The availability token IDE is transmitted by the second mesochronous unidirectional communication link LCUM2, as well as the second clock frequency H₂ of the second subcircuit SC2.

The first subcircuit SC1 includes a module for determining the number N of elementary memory locations available in the queue FIFO1, on the basis of the availability cues IDE transmitted by the second subcircuit SC2. The module for determining the number N of elementary memory locations available in the queue FIFO1 may be, for example, a counter, or, as represented in FIG. 1, the memory organized as a queue FIFO2, only the control part of which is used to determine the number N of elementary memory locations available in the queue FIFO1.

Thus, at any instant, the first synchronous subcircuit SC1 knows the maximum amount of data that it can transmit directly to the queue FIFO1 of the second synchronous subcircuit SC2 without waiting, between each data item dispatched, for an acknowledgement in return indicating that it is possible to transmit the next data item.

The bandwidth of the first mesochronous unidirectional communication link LCUM1 is then optimized.

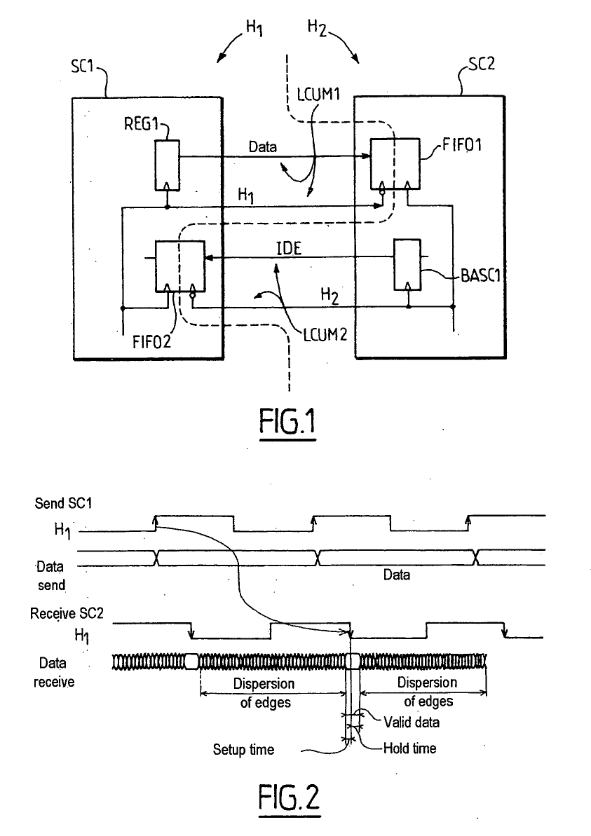

FIG. 2 illustrates a transmission of data over the first mesochronous unidirectional communication link LCUM1. The clock signal H₁ at the send end of the line is represented, as is the clock signal H₁ at the receive end of the line.

The data is sent on rising edges of the clock signal H₁ and sampled at reception on falling edges of the clock signal H₁.

In the course of the transmission of the data, the data transmitted disperse around a mean position corresponding to the send edge of the clock H₁, here the rising edge, under the effect of crosstalk.

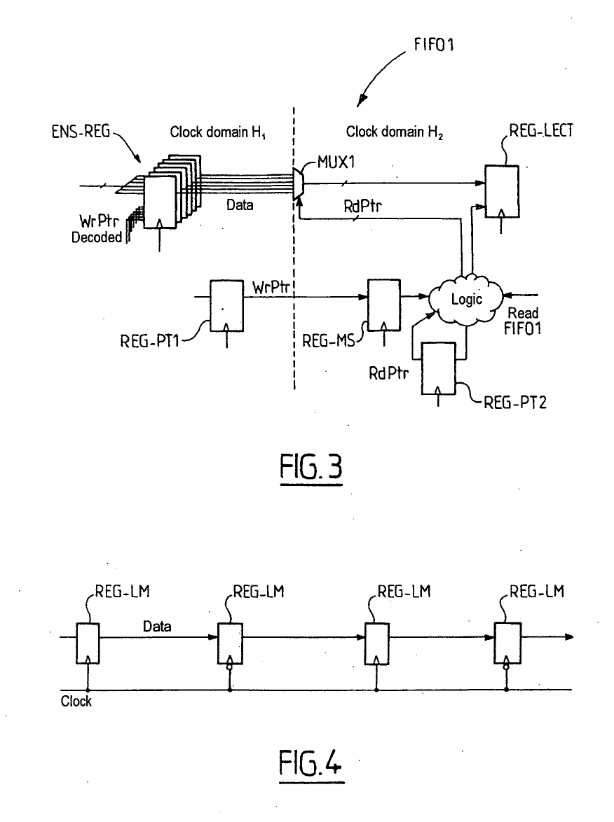

FIG. 3 represents an exemplary embodiment of the queue FIFO1. Such a queue, operating with two clock regulating frequencies H₁ and H₂, makes it possible to move asynchronously from one clock domain H₁ to the other H₂.

A dotted line represents the separation between the two clock domains H₁ and H₂. The clock domain H₁ includes a set ENS_REG of registers and a register REG_PT1.

The clock domain H₂ includes a multiplexer MUX1 linked at input to each of the registers of the set of registers ENS_REG.

Furthermore, the clock domain H₂ includes logical elements, a register REG_LECT, a register REG_MS, a register REG_PT2. The multiplexer MUX1 is connected to the register REG_LECT and to the logical elements. The logical elements are connected to the register REG_LECT, to the register REG_MS, as well as the register REG_PT2. The register REG_PT1 is connected to the register REG_MS.

The queue FIFO1 is write-regulated by the first clock frequency H₁, and is read-regulated by the second clock frequency H₂.

The selection of the data to be read and to be written from and to the queue FIFO1 is performed by means of two address pointers: a first address pointer WrPtr for writing, and a second address pointer RdPtr for reading. The first and second pointers WrPtr and RdPtr being incremented in their respective clock domain, they are respectively copied into the other domain.

The data is written to the set of registers ENS_REG. The register REG_PT1 stores the first pointer WrPtr.

Management of the full queue FIFO1 is done by a mechanism using tokens IDE representative of an available location in queue FIFO1. It is not necessary to have a copy of the second pointer RdPtr, because, initially, the first sender synchronous subcircuit SC1 has a limited number Nmax of elementary memory locations available in the queue FIFO1. As soon as the first synchronous subcircuit SC1 sends an item of data, it consumes one of these available elementary memory locations, and when it no longer has any location available (N=0), it can no longer send data to the second subcircuit SC2.

When queue FIFO1 is read, an elementary memory location is released and becomes available, and an availability token IDE for an additional elementary memory location in the queue FIFO1 is then dispatched to the first sender subcircuit SC1.

The first address pointer WrPtr travels through the register REG-MS as it is recopied from the first clock regulating frequency H₁ to the second clock regulating frequency H₂.

The register REG-PT2 makes it possible to store the second address pointer RdPtr, and the register REG-LECT makes it possible to store the data item read from the queue FIFO1 at the address of the second address pointer RdPtr.

FIG. 4 illustrates the transmission of data through a long-distance mesochronous unidirectional communication link, with intermediate synchronizations performed by means of the registers REG-LM, disposed in series on the link, and of the clock regulating frequency of the transmission sent to the registers REG_LM, alternatively inverted and noninverted.

Between two successive synchronizations, the propagation lag is identical for each data item, and for the clock regulating signal.

When the data transmission distances over a mesochronous unidirectional communication link are significant, one or more intermediate synchronizations may be necessary.

This makes it possible not to decrease the bit rate on a mesochronous unidirectional transmission link, even when the latter has a significant length. However, the intermediate synchronizations increase the latency of the data transfer, and hence the queue sizes, which must be increased accordingly.

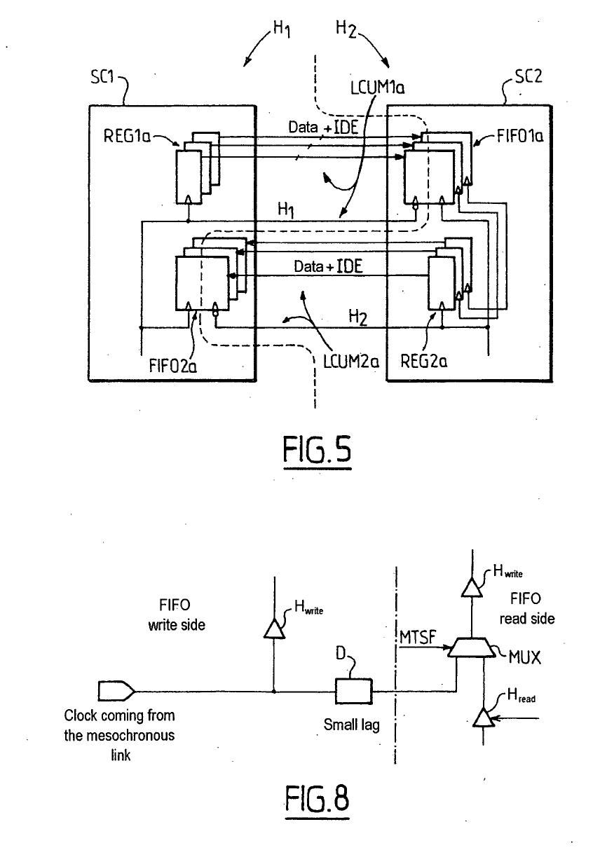

In FIG. 5, a variant of the system of FIG. 1 is adapted for pooling clock regulating frequencies.

A set LCUM1a of mesochronous unidirectional communication links makes it possible to transmit the requests from the first subcircuit SC1 to the second subcircuit SC2, and the responses to requests from the second subcircuit SC2 to the first subcircuit SC1.

A set LCUM2a of mesochronous unidirectional communication links makes it possible to transmit, from the second subcircuit SC2 to the first subcircuit SC1, the responses to the requests from the first subcircuit SC1 to the second subcircuit SC2 and the requests from the second subcircuit SC2 to the first subcircuit SC1.

The first subcircuit SC1 includes a plurality of registers REG1a for transmitting requests and response availability tokens to the second subcircuit SC2.

Each mesochronous unidirectional communication link of the set LCUM1a terminates respectively in a memory organized as a queue and belonging to a set of queues FIFO1a.

The second subcircuit SC2 is also furnished with a plurality REG2a of registers for sending, from the second subcircuit SC2 to the first subcircuit SC1, the responses to the requests and the availability tokens for the elementary memory locations of the queues of the set FIFO1a, through the respective mesochronous unidirectional communication links of the set LCUM2a.

Each mesochronous unidirectional communication link of the set LCUM2a includes a memory organized as a queue and belonging to a set of queues FIFO2a.

The embodiment makes it possible to pool the transfer of the clock regulating frequencies H₁ and H₂, for several mesochronous links.

Specifically, in this example, a single clock frequency H₁ is transmitted for the set LCUM1a of mesochronous unidirectional communication links, and a single clock frequency H₂ is transmitted for the set LCUM2a of mesochronous unidirectional communication links.

Clock signals are more protected and consume more energy than other signals. Sharing them decreases the production cost and the energy consumption of the circuit.

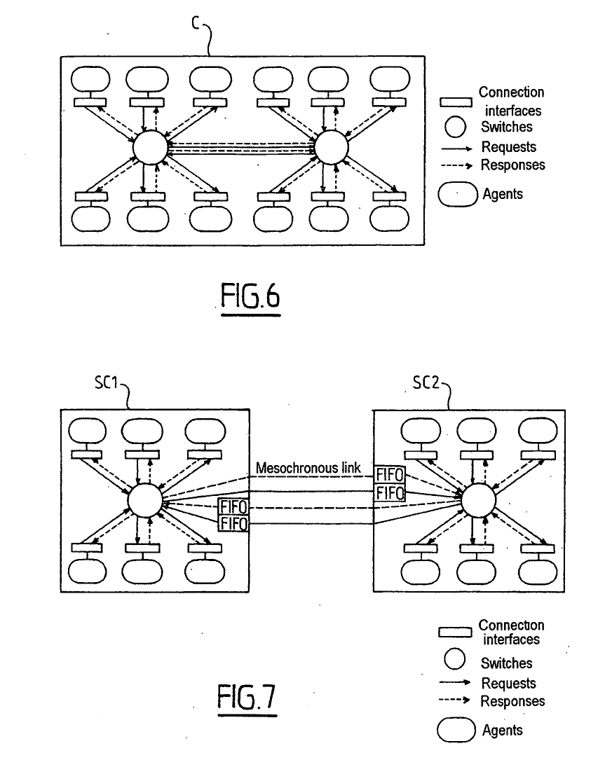

FIGS. 6 and 7 illustrate the partitioning of a circuit C into several subcircuits SC1, SC2 communicating together with mesochronous links terminated by queues.

Circuit C in FIG. 6 includes two switches, each linked to six agents furnished respectively with an interface for connection with the switch. Each switch communicates with an agent to which it is linked, by means of two opposite unidirectional links linking the switch and the agent's connection interface.

Furthermore, each switch communicates with the other switch, by means of two oppositely directed unidirectional links.

FIG. 7 represents two synchronous subcircuits SC1 and SC2.

The first subcircuit SC1 includes a switch linked to six agents furnished respectively with an interface for connection with the switch. The switch of the first subcircuit SC1 communicates with an agent to which it is linked, by means of two opposite unidirectional links linking the switch and the agent's connection interface.

The second subcircuit SC2 includes a switch linked to six agents furnished respectively with an interface for connection with the switch. The switch of the second subcircuit SC2 communicates with an agent to which it is linked, by means of two opposite unidirectional links linking the switch and the agent's connection interface.

The switches of the first subcircuit SC1 and of the second subcircuit SC2 are linked by oppositely directed mesochronous unidirectional communication links, each link including a queue at its end.

The system makes it possible to dispense with an expensive circuit-partitioning tool.

Specifically, time management involves a dispersion constraint, or difference in propagation times (“delay skew”), and may be adjusted by acting on the latency.

Each part can be synthesized independently. The emission registers possibly being close to the output connectors for a mesochronous link, the dispersion in the sending subsystems is very low.

At reception, because the queue is of small size, dispersion is easily controlled and remains low. In the subsystems, two steps are carried out: during a first step, all the paths are constrained in such a way as to obtain a low latency, and during a second step, a lag is added to the fastest paths, to decrease the dispersion.

Dispersion being low at the subsystems level, it is essentially present in the mesochronous links, and regardless of link length, intermediate synchronizations are possible, at the cost of an increase in latency.

It is therefore possible to ascertain the latency of the system, even though the subcircuits have not been finalized. A problem which conventionally is treated late on in a circuit design phase-is thus settled very early.

The splitting of the cycle time between the various subcircuits and the global interconnection system is replaced by the control of crosstalk on mesochronous links, this being simpler.

One thus obtains a circuit consisting of several synchronous subcircuits, having a size acceptable for computer-aided design tools, and which communicate with each other through mesochronous links terminating in asynchronous queues, by using the same communication protocol, on both the synchronous links and on the asynchronous links.

FIG. 8 illustrates a test module making it possible to test the circuit obtained, by synchronizing the read part of the queue and the write part.

A lag D is added to the clock regulating frequency H_{write} transmitted by a mesochronous unidirectional communication link, after transmission to the write part of the queue. The signal, with small lag D, is transmitted to a multiplexer MUX also receiving a signal of clock regulating frequency H_{read} in write mode for the queue. The multiplexer also receives, as input, a MTSF signal (Synchronous FIFO Test Mode), representative of the activation or non-activation of the test mode.

The clock regulation H_{write} transmitted by the mesochronous link is used for the writing to the queue.

The multiplexer MUX selects, when a signal MTSF has a predetermined value, the write clock regulating signal H_{write} with lag D for the reading of the queue, instead of the read clock regulating signal H_{read}.

Furthermore, an additional signal for each clock can be transmitted in the data, to indicate the state of the subsystem that sent the clock. For example, this signal may equal zero when the sender of the clock regulating signal is inactive, and one in the converse case.

This very rarely modified signal is pseudo-static and asynchronous. This makes it possible to stop and restart properly all communication links to still unavailable areas, when it is necessary to shut down a part of the system.

If, for example, it is decided to stop a subcircuit A, the signal sent by A will be driven to zero. When the subsystem B detects that this signal has been driven to zero, it resets to zero the exact number N of available elementary memory locations, and can therefore no longer send data to A.

When the subcircuit A is restarted, if the subcircuit B is itself available, it detects the signal indicating that the subcircuit A is active again, and then dispatches to the subcircuit A a number of availability tokens IDE for an additional elementary memory location IDE equal to the number of elementary memory locations available in its reception queue.

As soon as the subcircuit A receives an availability token IDE, it can commence sending data to the subcircuit B.

It is then possible to stop and to restart a subsystem without disturbing the operation of the whole assembly.

The method therefore makes it possible in particular to optimize energy consumption in a communication system.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description to the invention. Changes may be made in the elements described herein without departing from the spirit and scope of the invention as described in the following claims. In addition, it is to be understood that features described herein independently may, in certain embodiments, be combined.

What is claimed is:

1. System for on-circuit asynchronous communication, between synchronous subcircuits, comprising:
a first synchronous subcircuit regulated by a first clock frequency, suitable for sending requests to a second synchronous subcircuit regulated by a second clock frequency, the first subcircuit transmitting data to the second subcircuit through a first mesochronous unidirectional communication link, and the second subcircuit transmitting tokens to the first subcircuit through a second mesochronous unidirectional communication link;
wherein the first mesochronous unidirectional communication link comprises a memory organized as a queue situated at the end of communication of the first link, and wherein an elementary memory location of the queue has a predetermined size;
wherein the second synchronous subcircuit comprises sending means for transmitting to the first subcircuit availability tokens of an additional elementary memory location in the queue as soon as an elementary memory location of the queue is read by the second subsystem; and
the first subcircuit comprises means of transmission for transmitting directly to the second subcircuit data of a size at most equal to the size corresponding to the elementary memory locations available in the queue.

2. System according to claim 1, wherein the first subcircuit comprises means of determination of the number of elementary memory locations available, on the basis of the availability tokens.

3. System according to claim 1, wherein the queue is write-regulated by the first clock frequency, and read-regulated by the second clock frequency.

4. System according to claim 1, wherein the queue comprises a number of elementary memory locations, at least equal to the number of cycles of the clock having the lowest regulating frequency, allowing a transfer of data from the first subsystem to the second subsystem, and the transmission from the second subsystem to the first subsystem of a token of availability of an additional elementary memory location in the queue.

5. System according to claim 1, wherein a mesochronous unidirectional communication link comprises means of intermediate synchronization of the data transmitted by the link.

6. System according to claim 1, wherein a plurality of mesochronous unidirectional communication links, with the same direction, have a commonly transmitted clock regulating frequency.

7. System according to claim 1, further comprising means of testing of the system by a device for generating test vectors, the means of testing comprising means for rendering the queues synchronous.

8. System according to claim 2, further comprising means of stopping/starting the first and second subcircuits, the stopping/starting means comprising means of dispatching a signal representative of the activity of one of the subcircuits jointly with the respective signal representative of the clock regulating frequency of the subcircuit, means for resetting to zero the determined number of elementary memory locations available in the queue of the second subcircuit when the first subcircuit or the second subcircuit becomes inactive, and means for sending the number of availability tokens corresponding to the number of elementary memory locations available in the queue, when the first and second subcircuits are both active again.

9. Method of on-circuit asynchronous communication between synchronous subcircuits, the circuit comprising a first synchronous subcircuit regulated by a first clock frequency, suitable for sending requests to a second synchronous subcircuit regulated by a second clock frequency, the method comprising: transmitting data from the first subcircuit to the second subcircuit through a first mesochronous unidirectional communication link, and transmitting tokens from the second subcircuit to the first subcircuit through a second mesochronous unidirectional communication link,
wherein the first mesochronous unidirectional communication link comprises a memory organized as a queue situated at the end of communication of the link, an elementary memory location of the queue having a predetermined size, the method further comprising transmitting an availability token for an additional elementary memory location in the queue to the first subcircuit as soon as an elementary memory location of the queue is read by the second subcircuit, and
transmitting data of a size at most equal to the size corresponding to the elementary memory locations available in the queue from the first subcircuit to the said second subcircuit.

10. Method according to claim 9, wherein the circuit is tested with a device for generating test vectors, rendering the queues synchronous.

11. Method according to claim 9, wherein the stopping/starting of the first and second subcircuits comprises: dispatching a signal representative of the activity of one of the subcircuits jointly with the respective signal representative of the clock regulating frequency of the subcircuit; resetting to zero the determined number of elementary memory locations available in the queue of the second subcircuit when the first subcircuit or the second subcircuit becomes inactive; and sending the number of availability tokens corresponding to the number of elementary memory locations available in the queue, when the first and second subcircuits are both active again.

12. Use of the method according to claim 9 to perform a hierarchical partition of large circuits into small subcircuits with a simplified apportionment of time.
